(19) United States
(12) Patent Application Publication
(10) Pub. No.: US 2021/0408128 A1
(43) Pub. Date: Dec. 30, 2021

(54) QUANTUM DOT COLOR FILTER, DISPLAY PANEL AND DISPLAY DEVICE

(71) Applicant: SHENZHEN CHINA STAR OPTOELECTRONICS SEMICONDUCTOR DISPLAY TECHNOLOGY CO., LTD., Shenzhen (CN)

(72) Inventor: Wenxiang Peng, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/617,801

(22) PCT Filed: Oct. 29, 2019
(86) PCT No.: PCT/CN2019/114109

§ 371 Date: Nov. 27, 2019

(30) Foreign Application Priority Data
Jul. 26, 2019 (CN) 201910679799.4

(51) Int. Cl. H01L 27/32; H01L 51/50; H01L 51/52

(52) U.S. Cl. CPC H01L 27/322; H01L 51/502; H01L 51/0005; H01L 51/5284; H01L 51/5275

(57) ABSTRACT

A quantum dot (QD) color filter, a QD display panel, and a QD display device are provided. The QD color filter includes a substrate layer, a color filter layer, a protective layer, a QD film layer, a first optical medium layer and a second optical medium layer that are sequentially disposed. A refractive index of the first optical medium layer being greater than a refractive index of the second optical medium layer.

### BACKGROUND

### 1. Field of the Invention

The present disclosure relates to the field of display panel, more particularly, to a quantum dot (QD) color filter, a display panel printed and a display device.

### 2. Description of the Related Art

A quantum dot organic light emitting diode (QD-OLED) structure display has the advantages of slimness, flexibility, high color gamut, and the like, owing to its self-luminous characteristic of OLED elements and wide color gamut of QDs. A QD-OLED device is a double-layered structure. One side of the double-layered structure has blue OLEDs that serve as a backlight, and another side is a color filter containing a quantum dot film layer which functions as a light converter.

In a QD-OLED device, the QD layer in the QD color filter is utilized to convert the blue backlight into red and green light, thus achieving full color.

A description is provided with reference to FIG. 1. FIG. 1 is a structural schematic diagram of a QD display panel in the related art. The QD display panel comprises a color filter 1 and a backlight 2. The color filter 1 comprises a substrate layer 11, a color filter layer 12, a protective layer 13 and a QD film layer 14 that are sequentially disposed. Since a QD-OLED device is a self-luminous device, light emitted by the backlight 2 will propagate in different directions. Therefore, when light emitted by the backlight 2 passes through the color filter 1, part of the light is absorbed by the black matrix between the RGB pixels and part of the light has a shorter optical path in the QD film layer 14, and the utilization rate of backlight is finally lowered.

As a result, there is a need to develop a novel QD color filter to overcome the drawbacks in the related art.

### SUMMARY

One objective of the present disclosure is to provide a QD color filter, which can resolve the problems in the related art that part of the light is absorbed by the black matrix between the RGB pixels and part of the light has a shorter optical path in the QD film layer when light emitted by the OLED backlight passes through the QD color filter.

In order to achieve the above objective, the present disclosure provides a quantum dot (QD) color filter. The QD color filter comprises a substrate layer, a color filter layer, a protective layer, a QD film layer, a first optical medium layer and a second optical medium layer that are sequentially disposed. A refractive index of the first optical medium layer is greater than a refractive index of the second optical medium layer.

The color filter layer is used for absorbing light in the unexcited QD film layer. Furthermore, a light transmittance of the first optical medium layer is 90% or more.

Furthermore, a light transmittance of the second optical medium layer is 90% or more.

Furthermore, the refractive index of the first optical medium layer ranges from 1.6 to 2.5, the refractive index of the second optical medium layer ranges from 1 to 1.6.

Furthermore, a material of the protective layer is made of transparent material.

Furthermore, a material of the first optical medium layer comprises polyimide, silicon nitride or silicon oxide.

Furthermore, a material of the second optical medium layer comprises polyimide, silicon nitride or silicon oxide.

Furthermore, the QD film layer is formed by using an inkjet printing method. The technical advantage of inkjet printing is that it can control the position and volume of the dropped ink, so that film formation by printing can be achieved in a pixel-level area. In addition, the use of inkjet printing technology to fabricate the QD color filter can greatly reduce the production cost of the panel.

The present disclosure also provides a quantum dot (QD) display panel comprising a backlight and the above QD color filter.

Furthermore, the backlight is a blue backlight.

Furthermore, the QD film layer comprises a red QD film layer, a green QD film layer, and a transparent film layer. The red QD film layer is excited by the backlight to generate red light so as to form the red sub-pixel. The green QD film layer excited by the backlight to generate green light so as to form the green sub-pixel. Blue light generated by the backlight will pass through the transparent film layer to form the blue sub-pixel.

Furthermore, the color filter further comprises a black matrix, which is used for separating the color sub-pixels of different colors.

Another objective of the present disclosure is to provide a QD display device. The QD display device comprises a body. The QD display panel according to the present disclosure is disposed on the body.

In contrast to the related art, the beneficial effects of the present disclosure are as follows. The present disclosure provides a QD color filter, a display panel and a display device. The optically denser medium layer and the optically thinner medium layer are disposed on a surface of the QD film layer. By utilizing the refraction of light generated when the light emitted by backlight passes through the optically denser medium layer from the optically thinner medium layer, the part of the light absorbed by the black matrix is reduced. The utilization rate of backlight is increased. At the same time, the optical path of the light in the QD film layer is increased.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a structural schematic diagram of a QD display panel in the related art.

FIG. 2 is a structural schematic diagram of a QD color filter according to a preferred of the present disclosure.

FIG. 3 is a structural schematic diagram of a QD display panel according to the preferred embodiment of the present disclosure.

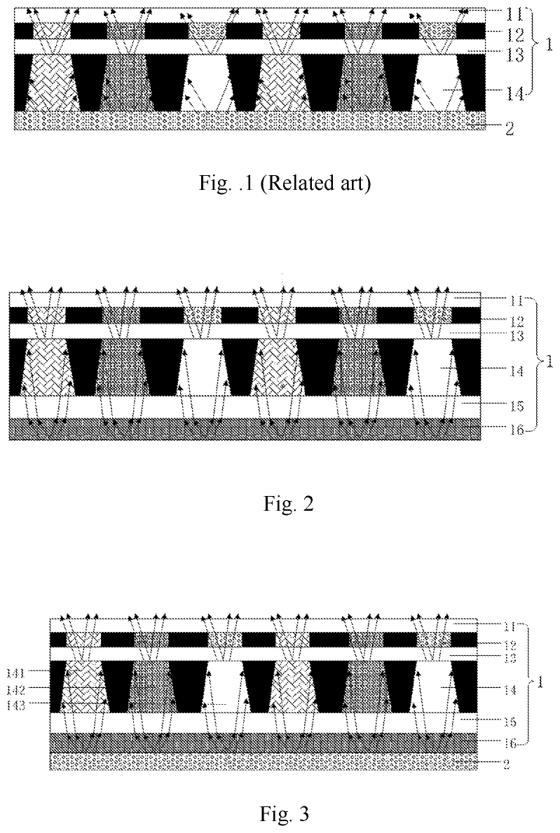

### DESCRIPTION OF THE EMBODIMENTS

For the purpose of description rather than limitation, the following provides such specific details as a specific system structure, interface, and technology for a thorough understanding of the application. However, it is understandable by persons skilled in the art that the application can also be implemented in other embodiments not providing such specific details. In other cases, details of a well-known apparatus, circuit and method are omitted to avoid hindering the description of the application by unnecessary details.

The invention is described below in detail with reference to the accompanying drawings, wherein like reference numerals are used to identify like elements illustrated in one or more of the figures thereof, and in which exemplary embodiments of the invention are shown. This invention may, however, be embodied in many different forms and should not be construed as limited to the particular embodiments set forth herein. Rather, these embodiments are provided so that this disclosure will be thorough and complete, and will fully convey the scope of the invention to those skilled in the art.

The present embodiment provides a QD color filter. A description is provided with reference to FIG. 2. FIG. 2 is a structural schematic diagram of a QD color filter 1 according to one embodiment of the present disclosure.

The color filter 1 comprises a plurality of pixels. Each of the pixels comprises a plurality of color sub-pixels of different colors. The color sub-pixels comprise a red sub-pixel, a green sub-pixel, and a blue sub-pixel.

The color filter 1 comprises a substrate layer 11, a color filter layer 12, a protective layer 13 and a QD film layer 14 that are sequentially disposed. The color filter layer 12 is used for absorbing light in the unexcited QD film layer 14 and reducing excitation of the QD film layer 14 by the ambient light. The protective layer 13 is used for protecting the color filter layer. In the present embodiment, a material of the protective layer 14 is a transparent material.

The QD film layer 14 is formed by using an inkjet printing method. The technical advantage of inkjet printing is that it can control the position and volume of the dropped ink, so that film formation by printing can be achieved in a pixel-level area. In addition, the use of inkjet printing technology to fabricate the QD color filter can greatly reduce the production cost of the panel.

The present embodiment further provides a QD display panel. A description is provided with reference to FIG. 3. FIG. 3 is a structural schematic diagram of a QD display panel according to one embodiment of the present disclosure. The display panel comprises a color filter 1 and a backlight 2 that are sequentially disposed.

The backlight 2 is a blue backlight. The QD film layer 14 comprises a red QD film layer 141, a green QD film layer 142, and a transparent film layer 143. The red QD film layer 141 is excited by the backlight 2 to generate red light so as to form the red sub-pixel.

The green QD film layer 142 is excited by the backlight 2 to generate green light so as to form the green sub-pixel. Blue light generated by the backlight 2 will pass through the transparent film layer 143 to form the blue sub-pixel.

The color filter 1 further comprises a black matrix, which is used for separating the color sub-pixels of different colors.

Since the QD display panel is a self-luminous device, light emitted by the backlight 2 will propagate in different directions. Therefore, when light emitted by the backlight 2 passes through the color filter 1, part of the light is absorbed by the black matrix between the red sub-pixels, the green sub-pixels and the blue sub-pixels, and part of the light has a shorter optical path in the QD film layer 14. The utilization rate of backlight is finally lowered.

When light propagates from an optically thinner medium to an optically denser medium, light refraction occurs. At this time, the angle of refraction of the refracted light is smaller than the incident angle of the incident light, thus changing the propagation direction of the light.

In the present embodiment, a first optical medium layer 15 and a second optical medium layer 16 are sequentially disposed on the QD film layer 14. A refractive index of the first optical medium layer 15 is greater than a refractive index of the second optical medium layer 16, so that the first optical medium layer 15 is an optically denser medium and the second optical medium layer 16 is an optically thinner medium.

The refractive index of the first optical medium layer 15 ranges from 1.6 to 2.5. The refractive index of the second optical medium layer 16 ranges from 1 to 1.6.

When light emitted by the backlight 2 propagates from the second optical medium layer 16 to the first optical medium layer 15, refraction occurs, and the light absorbed by the black matrix is reduced. As a result, the backlight utilization rate and the light conversion efficiency of the QD film layer can be increased.

A light transmittance of the first optical medium layer 15 is 90% or more. A light transmittance of the second optical medium layer 16 is also 90% or more.

A material of the first optical medium layer 15 may be polyimide, or may be silicon nitride or silicon oxide, and the present disclosure is not limited in this regard.

A material of the second optical medium layer 16 may be polyimide, or may be silicon nitride or silicon oxide, and the present disclosure is not limited in this regard.

The optically denser medium layer and the optically thinner medium layer are disposed on a surface of the QD film layer according to the present embodiment. By utilizing the refraction of light generated when the light emitted by backlight passes through the optically denser medium layer from the optically thinner medium layer, the part of the light absorbed by the black matrix is reduced. The utilization rate of backlight is increased. At the same time, the optical path of the light in the QD film layer is increased.

A QD display device is further provided according to the present embodiment. The QD display device comprises a body. The QD display panel according to the present disclosure is disposed on the body.

The beneficial effects of the present disclosure are as follows. The present disclosure provides a QD color filter, a display panel and a display device. The optically denser medium layer and the optically thinner medium layer are disposed on a surface of the QD film layer. By utilizing the refraction of light generated when the light emitted by backlight passes through the optically denser medium layer from the optically thinner medium layer, the part of the light absorbed by the black matrix is reduced. The utilization rate of backlight is increased. At the same time, the optical path of the light in the QD film layer is increased.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

1. A quantum dot (QD) color filter comprising a substrate layer, a color filter layer, a protective layer, a QD film layer, a first optical medium layer and a second optical medium layer that are sequentially disposed, wherein a refractive index of the first optical medium layer being greater than a refractive index of the second optical medium layer.

2. The QD color filter as claimed in claim 1, wherein the refractive index of the first optical medium layer ranges from 1.6 to 2.5, the refractive index of the second optical medium layer ranges from 1 to 1.6.

3. The QD color filter as claimed in claim 1, wherein a material of the first optical medium layer comprises polyimide, silicon nitride or silicon oxide.

4. The QD color filter as claimed in claim 1, wherein a material of the second optical medium layer comprises polyimide, silicon nitride or silicon oxide.

5. The QD color filter as claimed in claim 1, wherein a light transmittance of the first optical medium layer is 90% or more.

6. The QD color filter as claimed in claim 1, wherein a light transmittance of the second optical medium layer is 90% or more.

7. The QD color filter as claimed in claim 1, wherein the QD film layer is formed by using an inkjet printing method.

8. A quantum dot (QD) display panel comprising:
a backlight; and
a quantum dot (QD) color filter comprising: a substrate layer, a color filter layer, a protective layer, a QD film layer, a first optical medium layer and a second optical medium layer that are sequentially disposed, wherein a refractive index of the first optical medium layer being greater than a refractive index of the second optical medium layer.

9. The QD display panel as claimed in claim 8, wherein the refractive index of the first optical medium layer ranges from 1.6 to 2.5, the refractive index of the second optical medium layer ranges from 1 to 1.6.

10. The QD display panel as claimed in claim 8, wherein a material of the first optical medium layer comprises polyimide, silicon nitride or silicon oxide.

11. The QD display panel as claimed in claim 8, wherein a material of the second optical medium layer comprises polyimide, silicon nitride or silicon oxide.

12. The QD display panel as claimed in claim 8, wherein a light transmittance of the first optical medium layer is 90% or more.

13. The QD display panel as claimed in claim 8, wherein a light transmittance of the second optical medium layer is 90% or more.

14. The QD display panel as claimed in claim 8, wherein the QD film layer is formed by using an inkjet printing method.

15. The QD display panel as claimed in claim 8, wherein the backlight is a blue backlight.

16. A quantum dot (QD) display device comprising:
a body; and
a quantum dot (QD) color filter comprising: a substrate layer, a color filter layer, a protective layer, a QD film layer, a first optical medium layer and a second optical medium layer that are sequentially disposed, wherein a refractive index of the first optical medium layer being greater than a refractive index of the second optical medium layer.

17. The QD display device as claimed in claim 16, wherein the refractive index of the first optical medium layer ranges from 1.6 to 2.5, the refractive index of the second optical medium layer ranges from 1 to 1.6.

18. The QD display device as claimed in claim 16, wherein a material of the first optical medium layer comprises polyimide, silicon nitride or silicon oxide.

19. The QD display device as claimed in claim 16, wherein a material of the second optical medium layer comprises polyimide, silicon nitride or silicon oxide.

20. The QD display device as claimed in claim 16, wherein a light transmittance of the first optical medium layer is 90% or more.
